(19) United States
(12) Patent Application Publication
(10) Pub. No.: US 2025/0364288 A1
(43) Pub. Date: Nov. 27, 2025

(54) APPARATUS FOR PROCESSING SUBSTRATE

(71) Applicant: WONIK IPS CO., LTD., Pyeongtaek-si (KR)

(72) Inventors: Joo Ho KIM, Pyeongtaek-si (KR); Joo Suop KIM, Pyeongtaek-si (KR); Sang Rok NAM, Pyeongtaek-si (KR); Jeong Lim SON, Pyeongtaek-si (KR); Jae Hwan LIM, Pyeongtaek-si (KR); Da Eun HYUN, Pyeongtaek-si (KR)

(21) Appl. No.: 19/214,377

(22) Filed: May 21, 2025

(30) Foreign Application Priority Data
May 21, 2024 (KR) 10-2024-0065903

(51) Int. Cl. H01L 21/673; H01L 21/67

(52) U.S. Cl. CPC H01L 21/67306; H01L 21/67017

(57) ABSTRACT

An embodiment relates to a substrate processing apparatus configured to discharge liquefied fluid. The apparatus may include a reaction tube unit that has an open lower end and defines a reaction space in which a plurality of substrates are processed, a boat unit that is disposed within the reaction tube unit and supports the plurality of substrates in a vertically stacked arrangement, and a boat support unit that supports and vertically moves the boat unit so as to position the boat unit within the reaction space. At least a portion of one surface of the boat support unit may be inclined to allow liquefied fluid in the reaction space to flow downward and be discharged.

### CROSS-REFERENCE TO RELATED PATENT APPLICATION

This application claims the benefit under 35 U.S.C. § 119 of Korean Patent Application No. 10-2024-0065903, filed on May 21, 2024, the disclosure of which is hereby incorporated by reference in its entirety.

### BACKGROUND

### 1. Field of the Disclosure

The present invention relates to an apparatus for processing a substrate and, more particularly, to a substrate processing apparatus with improved exhaust performance.

### 2. Description of the Related Art

A substrate processing apparatus performs processing operations on substrates such as wafers. For such processing, a boat loaded with a predetermined number of substrates is vertically moved within a loading region, either ascending for substrate processing or descending for unloading the processed substrates.

More specifically, the substrate processing apparatus includes a processing unit that accommodates the substrate and forms a sealed reaction space isolated from the external environment, a gas supply unit configured to supply process gases such as precursor gas, reaction gas, and carrier gas into the interior of the processing unit to control its internal pressure, and a gas exhaust unit configured to discharge the supplied process gases in order to regulate the internal pressure of the processing unit.

During the substrate processing operation of the aforementioned apparatus, residues remaining on the substrate or thin film surface can cause a reduction in yield, thereby necessitating the development of techniques for removing such residues.

As a method of removing residues from the substrate or thin film surface, techniques employing rapid temperature and pressure changes within the reaction space of the processing unit have been adopted. In such conventional substrate processing apparatuses, a thermal insulation container or heat shield plate is provided below the boat to thermally insulate the loading region from the reaction space, particularly in cases where the lower end of a vertically elongated bar remains at a relatively low temperature. Consequently, as the boat ascends, the temperature of the cap flange, which seals the reaction space, abruptly drops. This sudden temperature decrease results in partial liquefaction of the process gas.

In conventional substrate processing apparatuses that use water vapor (H₂O) during processing, the low temperature at the lower cap flange causes condensation to occur on the cap flange, resulting in the accumulation of condensed water. The accumulated water may lead to corrosion of internal structural components or flow into the drain tank, thereby causing damage to the tank.

### SUMMARY OF THE DISCLOSURE

The present disclosure has been devised to address the above-described and other problems. It is an object of the disclosure to provide a substrate processing apparatus in which condensation occurring inside the reaction space and near the cap flange can be prevented through structural improvements, and in which fluids such as condensate can be effectively managed, thereby preventing corrosion of internal structures. However, it should be understood that the problems described herein are illustrative and are not intended to limit the scope of the present disclosure.

According to one aspect of the present disclosure, a substrate processing apparatus is provided. The apparatus includes a reaction tube unit that has a lower open end and defines a reaction space in which a plurality of substrates are processed. A boat unit is disposed inside the reaction tube unit and is configured to support the substrates in a vertically stacked arrangement. A boat support unit supports the boat unit and moves the boat unit vertically so that the boat unit can be positioned within the reaction space.

The boat support unit may be configured such that at least a portion of one surface of the boat support unit includes an inclined region, such that liquefied fluid in the reaction space is discharged downward.

In one embodiment of the present disclosure, the boat support unit includes a thermal cap formed below the boat unit. The thermal cap contains a heat-insulating region to reduce thermal loss from a lower portion of the reaction space near the outer side of the boat support unit. A rotation flange is disposed below the thermal cap and is connected to a drive unit located below the boat support unit. The rotation flange is rotated by the driving force of the drive unit and transmits the rotational force to the thermal cap and the boat unit. A cap flange is disposed below the rotation flange, and is coupled to the drive unit at a central portion thereof. The cap flange supports the boat support unit and drives the boat support unit vertically. A shield plate is coupled to an upper surface of the cap flange to protect it from corrosive gases.

According to one embodiment of the present disclosure, the boat support unit includes a thermal cap formed below the boat unit. The thermal cap includes a heat-insulating region therein to prevent thermal loss in a lower region of the reaction space adjacent to the outer side of the boat support unit. The thermal cap may be formed such that its lower surface gradually slopes downward from a central region toward an edge.

According to another embodiment of the present disclosure, the boat support unit includes a thermal cap formed below the boat unit. The thermal cap includes a heat-insulating region to prevent thermal loss in a lower region of the reaction space near the outer side of the boat support unit. At least a portion of the lower surface of the thermal cap may be formed with the inclined region having a first slope.

According to still another embodiment of the present disclosure, the boat support unit includes a rotation flange that is connected to a drive unit located below the boat support unit. The rotation flange is rotated by the driving force of the drive unit and transmits the rotational force to the boat unit. The rotation flange may include a flange upper surface portion that slopes downward from a central region toward an edge. A plurality of through-holes may be formed in a radially equidistant arrangement with respect to the center of the rotation flange and extend vertically through the rotation flange. The rotation flange may also include a plurality of lateral discharge portions formed to penetrate from an inner side to an outer side of a flange sidewall that surrounds the perimeter of the rotation flange and is formed higher than the flange upper surface portion, the lateral discharge portions being located at positions corresponding to the flange upper surface portion.

According to another embodiment of the present disclosure, the boat support unit includes a rotation flange that is connected to a drive unit formed below the boat support unit. The rotation flange is rotated by the driving force of the drive unit and transmits the rotational force to the boat unit. The rotation flange may include an inclined region formed on at least a portion of the flange upper surface, the inclined region having a second slope.

According to yet another embodiment of the present disclosure, the boat support unit includes a shield plate coupled to the upper surface of a cap flange that supports the boat support unit and drives its vertical movement. The shield plate is configured to protect the upper surface of the cap flange from corrosive gases. The shield plate may include a shield upper surface portion that has at least a part formed with an inclined region, and a shield through-hole formed at a location spaced a predetermined distance from the center of the shield plate and penetrating through the shield plate.

According to an embodiment of the present disclosure, the shield through-hole may be formed either as a hole portion that penetrates vertically through the shield plate in a hole shape at radially equidistant positions with respect to the center of the shield plate, or as a slit portion that penetrates in the form of a slit.

According to another embodiment of the present disclosure, the shield upper surface portion may be formed such that it slopes gradually downward from a central region toward the shield through-hole, and also slopes gradually downward from the edge toward the shield through-hole.

According to still another embodiment of the present disclosure, the shield plate may include an inclined region in which at least one portion of the shield upper surface portion has a third slope, and at least another portion has a fourth slope.

According to yet another embodiment of the present disclosure, the boat support unit includes a cap flange to which the drive unit formed below the boat support unit is coupled at a central region thereof. The cap flange supports the entire boat support unit and provides vertical drive movement. The cap flange may include a shield seating portion formed on its upper surface for supporting the shield plate, a drive coupling portion formed as a vertically penetrating hole at the center of the cap flange to allow coupling with the drive unit, a discharge guide groove formed as a ring-shaped groove centered around the center of the cap flange at a predetermined radial distance, and a bottom discharge portion formed at one or more locations along the discharge guide groove and penetrating vertically through the cap flange.

According to certain embodiments of the present disclosure, an inclined region may be formed in at least a portion of the structure to allow fluid to flow downward. This configuration can prevent corrosion of internal structural components caused by the fluid, and the fluid may be directed to a scrubber, thereby preventing damage to the drain tank during the cleaning process. Of course, these effects are merely illustrative and should not be construed as limiting the scope of the present disclosure.

### BRIEF DESCRIPTION OF THE DRAWINGS

The above and other features and advantages of the present disclosure will become more apparent by describing in detail embodiments thereof with reference to the attached drawings in which:

FIG. 1 is a cross-sectional view illustrating a substrate processing apparatus according to an embodiment of the present disclosure.

FIG. 2 is a cross-sectional view illustrating a boat support unit of the substrate processing apparatus according to an embodiment of the present disclosure.

FIG. 3 is an exploded perspective view illustrating the boat support unit according to an embodiment of the present disclosure.

FIG. 4 is an exploded cross-sectional view of the boat support unit shown in FIG. 3.

FIG. 5 is a perspective view illustrating a thermal cap of the boat support unit according to an embodiment of the present disclosure.

FIG. 6 is a cross-sectional view of the thermal cap according to an embodiment of the present disclosure.

FIG. 7 is a perspective view illustrating a rotation flange of the boat support unit according to an embodiment of the present disclosure.

FIG. 8 is a cross-sectional view taken along line B-B′ of FIG. 7.

FIG. 9 is a cross-sectional view taken along line C-C′ of FIG. 7.

FIG. 10 is a perspective view illustrating a shield plate of the boat support unit according to an embodiment of the present disclosure.

FIG. 11 is a cross-sectional view of the shield plate according to an embodiment of the present disclosure.

FIG. 12 is a perspective view illustrating a cap flange of the boat support unit according to an embodiment of the present disclosure.

FIG. 13 is a cross-sectional view of the cap flange according to an embodiment of the present disclosure.

FIG. 14 is a diagram illustrating the discharge of fluid from the boat support unit according to an embodiment of the present disclosure.

### DETAILED DESCRIPTION OF THE DISCLOSURE

Hereinafter, preferred embodiments of the present disclosure will be described in detail with reference to the accompanying drawings. These embodiments are provided to more fully explain the present disclosure to those skilled in the art. Various modifications may be made to the embodiments, and the scope of the present disclosure is not intended to be limited to the specific embodiments set forth below. Rather, these embodiments are provided to more completely describe the present disclosure and to fully convey the spirit of the disclosure to those skilled in the art.

In the drawings, the thicknesses and dimensions of individual layers or components may be exaggerated for clarity and ease of understanding. The embodiments of the present disclosure are described with reference to the drawings that schematically illustrate ideal implementations of the present disclosure. Variations in shape may be anticipated due to manufacturing techniques and/or tolerances. Therefore, the embodiments of the inventive concept should not be construed as being limited to the specific shapes of the regions illustrated in the drawings, but should include deviations in shape arising from manufacturing processes.

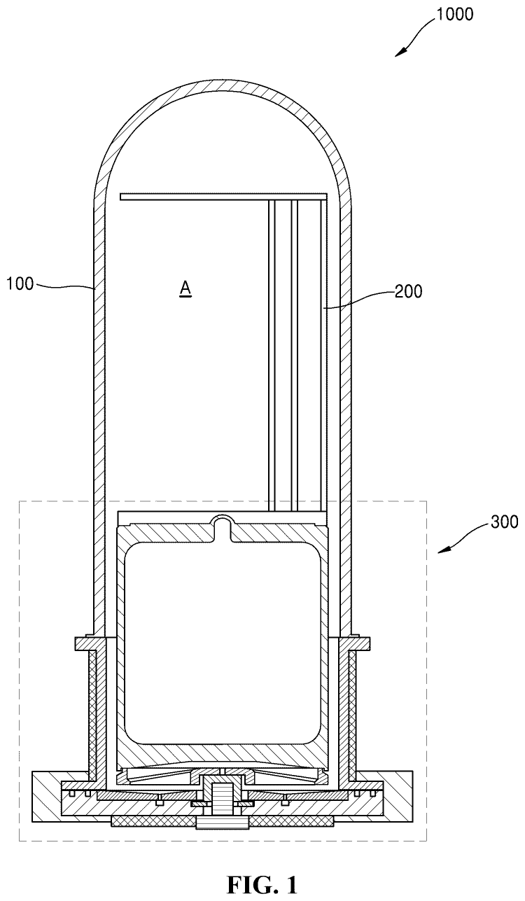

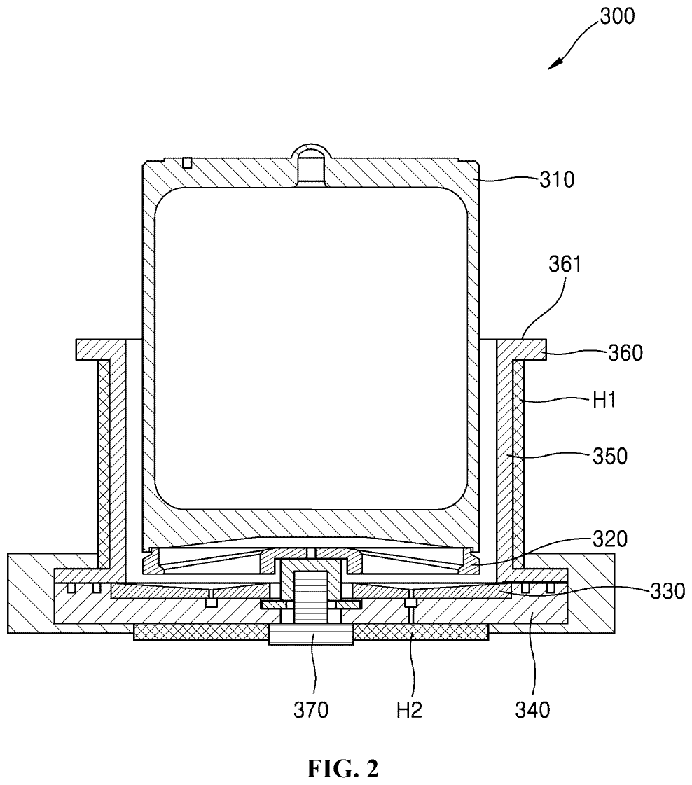

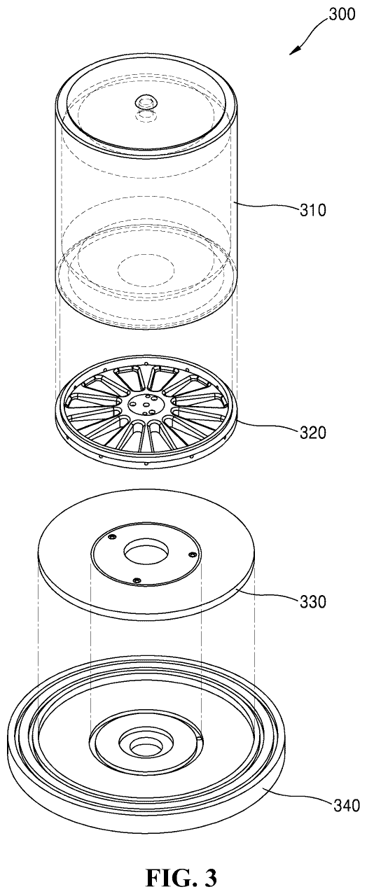

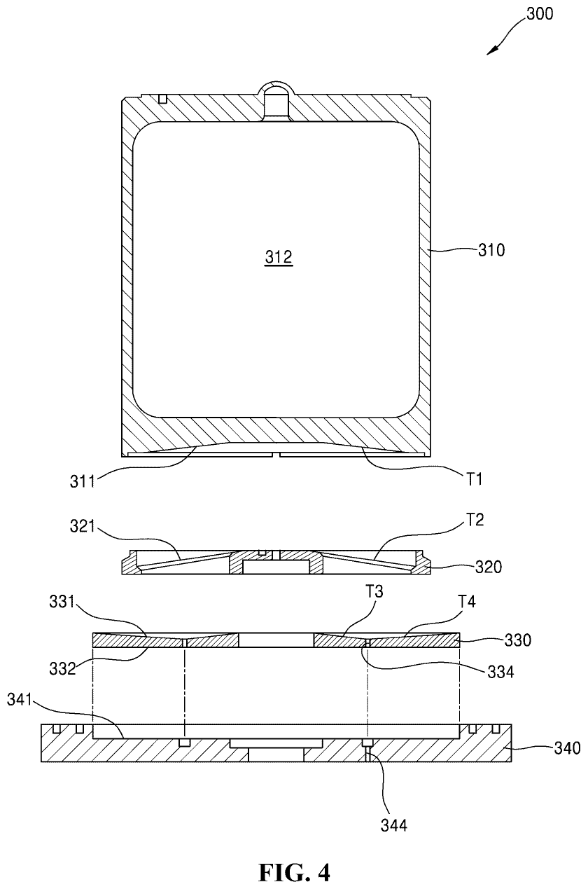

FIG. 1 is a cross-sectional view illustrating a substrate processing apparatus 1000 according to an embodiment of the present disclosure. FIG. 2 is a cross-sectional view illustrating a boat support unit 300 of the substrate processing apparatus 1000, and FIGS. 3 and 4 are exploded perspective and exploded cross-sectional views, respectively, of the boat support unit 300.

Referring first to FIG. 1, a substrate processing apparatus 1000 according to certain embodiments of the present disclosure may generally include a reaction tube unit 100, a boat unit 200, and a boat support unit 300.

As illustrated in FIG. 1, the reaction tube unit 100 may be a structure having an open lower end and forming a reaction space A in which a plurality of substrates are processed. For example, the reaction tube unit 100 may have an internal receiving space configured to accommodate a plurality of substrates or a boat unit 200 on which the substrates are mounted. A gas supply device or a gas exhaust device may be provided to supply or discharge process gases or cleaning gases into or from the receiving space. Accordingly, the receiving space may serve as the reaction space A.

The substrates processed in the reaction space may include, for example, semiconductor substrates, display substrates for LED or LCD devices, solar cell substrates, or glass substrates, but are not limited thereto and may include any other type of processable substrate.

The reaction tube unit 100 may be a type of furnace or a tubular structure including a furnace, in which a lower passage is formed to allow loading and unloading of a boat unit 200 on which a plurality of substrates are placed.

A heater may be installed around the reaction tube unit 100 to maintain a high-temperature environment, and at least a part of the reaction tube unit may be made of a heat-resistant material such as quartz, metal, or ceramic to withstand the high temperatures generated by the heater. Preferably, the reaction tube unit 100 is formed of quartz.

The reaction tube unit 100 may be formed in a double-wall structure to accommodate pressurized process conditions.

As shown in FIG. 1, the boat unit 200 may be disposed inside the reaction tube unit 100 and may be a structure in which a plurality of substrates are vertically stacked and seated.

For example, before the boat unit 200 is introduced into the reaction tube unit 100, a plurality of substrates may be loaded onto a plurality of seating regions formed on the boat unit 200, such that the substrates are seated in a stacked arrangement. The boat unit 200 may be formed of a quartz structure.

According to certain embodiments of the present disclosure, a temperature sensor may be provided on a lateral side of the boat unit 200. The temperature sensor may be configured to measure the temperature of the reaction space A and enable uniform temperature control therein. For example, the temperature sensor may be a profile thermocouple (profile T/C).

The boat support unit 300 supports the boat unit 200 and may be a structure configured to move the boat unit 200 vertically so that it can be positioned within the reaction space A of the reaction tube unit 100.

More specifically, before the boat unit 200 is introduced into the reaction tube unit 100, a plurality of substrates may be seated on the boat unit 200, and to process these substrates, the boat unit 200 may be moved vertically into the interior of the reaction tube unit 100.

After processing is completed within the reaction space A, the boat unit 200 may be lowered below the reaction tube unit 100 so that the substrates can be unloaded.

As the boat unit 200 is elevated into the reaction space A, the boat support unit 300 may be coupled to the lower end of the reaction tube unit 100 to seal the bottom of the reaction tube unit, thereby serving as a cover for the reaction tube unit 100.

The substrate processing apparatus of the present disclosure may be applied to substrate processing using process gases such as H₂, NH₃, O₂, H₂O, or F, and more specifically, H₂O may be used during the substrate processing.

In this case, the boat support unit 300 may be configured to discharge condensed fluid in order to prevent degradation in exhaust performance due to water pooling caused by liquefaction within the boat support unit 300.

For example, the boat support unit 300 may be formed such that at least a portion of one side of the boat support unit 300 includes an inclined region, so that a liquefied fluid in the reaction space A is discharged downward.

Specifically, as illustrated in FIGS. 2 through 4, the boat support unit 300 may include a thermal cap 310, a rotation flange 320, a shield plate 330, and a cap flange 340.

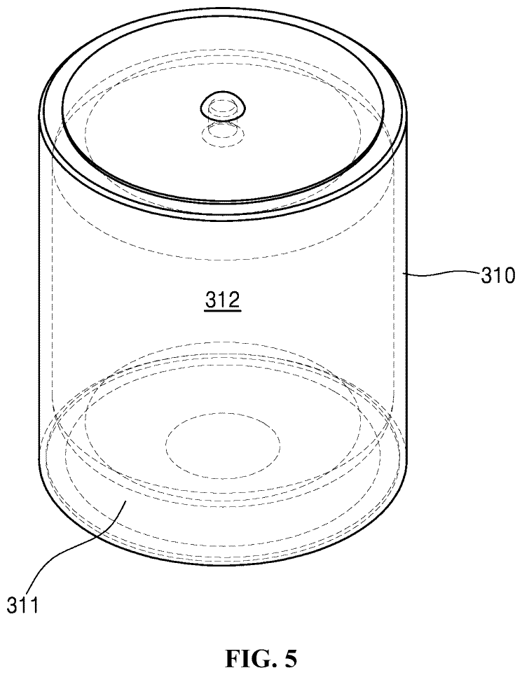

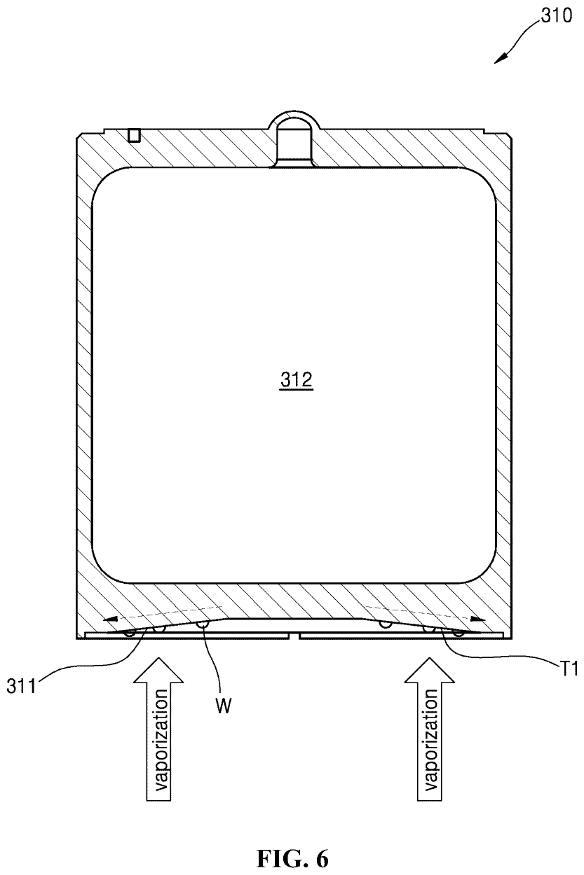

FIG. 5 is a perspective view illustrating the thermal cap 310 of the boat support unit 300 according to an embodiment of the present disclosure, and FIG. 6 is a cross-sectional view of the thermal cap 310.

As illustrated in FIGS. 5 and 6, the thermal cap 310 may be formed below the boat unit 200 and may have a tank-shaped structure with a heat-insulating region 312 formed inside.

The heat-insulating region 312 may be formed of an insulating material configured to block heat transfer at the upper and lower portions of the thermal cap 310, or it may be formed as an air layer composed solely of air to suppress convection.

The boat unit 200 may be installed above the thermal cap 310. When the boat support unit 300 is elevated and the boat unit 200 is introduced into the reaction tube unit 100, at least a portion of an upper part of the thermal cap 310 may be positioned inside the reaction tube unit 100.

That is, the reaction space A inside the reaction tube unit 100 is maintained at a high temperature for substrate processing. In this state, the tank-shaped thermal cap 310 introduced into the inner region of the reaction tube unit 100 may serve to prevent heat loss in the lower region of the reaction space A near the outer side of the boat support unit 300.

On a lower surface of the thermal insulation cap 310, which is referred to as the thermal insulation cap lower surface 311, moisture such as H₂O that vaporizes from a lower region of the boat support unit 300 and rises may condense into fluid and accumulate.

In this case, in order to discharge the fluid accumulated on the thermal insulation cap lower surface 311, the inclined region for allowing the fluid to flow downward may be formed on the thermal insulation cap lower surface 311.

Specifically, the thermal insulation cap 310 may include the inclined region formed such that at least a portion of the thermal insulation cap lower surface 311 has a first slope T1.

For example, as shown in FIG. 6, the thermal cap 310 may be formed such that the thermal cap lower surface 311 slopes gradually downward from its center toward the edge. Accordingly, liquefied fluid that has formed on the thermal cap lower surface 311 may flow toward the edge along the first slope T1 and then be discharged downward.

The thermal cap 310 may be formed of quartz.

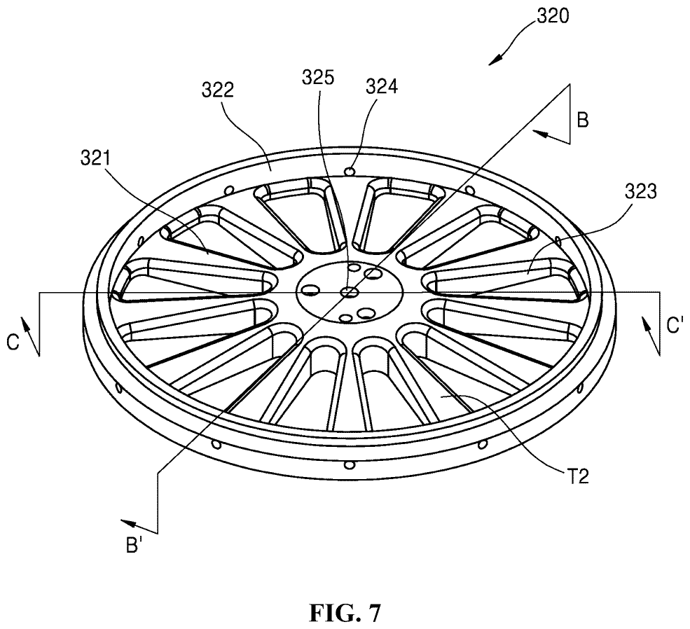

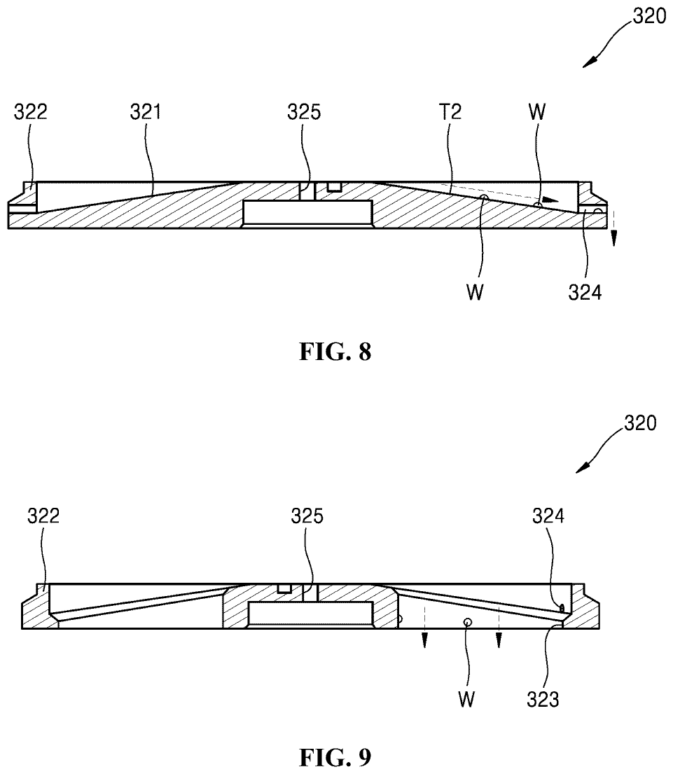

FIG. 7 is a perspective view illustrating the rotation flange 320 of the boat support unit 300 according to an embodiment of the present disclosure. FIG. 8 is a cross-sectional view taken along line B-B′ of FIG. 7, and FIG. 9 is a cross-sectional view taken along line C-C′ of FIG. 7.

As shown in FIGS. 2 through 4, the rotation flange 320 may be positioned below the thermal cap 310. The rotation flange 320 may be connected to a drive unit 370 formed below the boat support unit 300 and may be rotated by the driving force of the drive unit 370.

In other words, the rotation flange 320 may be rotated by the rotational force of the drive unit 370, and as it rotates, it may transmit the rotational force to the thermal cap 310 and the boat unit 200 to rotate the thermal cap 310 disposed above the rotation flange 320.

As shown in FIG. 8, the rotation flange 320 may include the inclined region formed such that at least a portion of the flange upper surface portion 321 has a second slope T2 to allow liquefied H₂O to flow downward.

More specifically, the rotation flange 320 may include a flange upper surface portion 321, a flange sidewall portion 322, a plurality of through-holes 323, and lateral discharge portions 324.

As shown in FIGS. 7 and 8, the flange upper surface portion 321 may be the upper surface of a body portion constituting the rotation flange 320, which is circular in shape, excluding the plurality of through-holes 323.

The flange upper surface portion 321 may be formed to gradually slope downward from a central region to an outer edge of an upper surface of the rotation flange 320. Accordingly, fluid falling from the thermal insulation cap 310 may flow along the second slope T2 on the flange upper surface portion 321 toward the outer edge of the flange upper surface portion 321.

As shown in FIGS. 7 and 8, the flange sidewall 322 may be formed to surround an outer periphery of the rotation flange 320 and may be higher than the flange upper surface portion 321. Specifically, the flange upper surface portion 321 may be formed such that an outer edge of the flange upper surface portion 321 is lower than its central region according to the second slope T2. Relatively, the flange sidewall 322 may be formed higher than the outer edge of the flange upper surface portion 321 and may have a shape resembling a wall.

As shown in FIGS. 7 and 9, the plurality of through-holes 323 may be openings formed to penetrate vertically through the rotation flange 320. Accordingly, fluid dropped from the thermal cap 310 may pass through the rotation flange 320 via the plurality of through-holes 323.

The plurality of through-holes 323 may be formed in a radially equiangular arrangement with respect to the center of the rotation flange 320. That is, the plurality of through-holes 323 may be formed at radially equal intervals in the rotation flange 320, which has a circular plate shape, so that the structure may be formed in a shape that resembles a bicycle or automobile wheel in its entirety. This configuration may enable smooth movement of airflow within the boat support unit 300.

The flange upper surface portion 321 surrounding the plurality of through-holes 323 may be chamfered and inclined inward toward the center of the through-holes 323. As a result, fluid falling from the thermal cap 310 may flow either toward the edge of the flange upper surface portion 321 or into the plurality of through-holes 323.

As illustrated in FIGS. 7 and 8, the lateral discharge portions 324 may be formed to penetrate from an inner side to an outer side of the flange sidewall 322.

The lateral discharge portions 324 may be located at positions corresponding to the flange upper surface portion 321.

Accordingly, as shown in FIG. 8, fluid that flows toward the outer edge along the second slope T2 of the flange upper surface portion 321 may be discharged to an outer side of the rotation flange 320 through the lateral discharge portions 324, thereby preventing the fluid from accumulating inside the flange sidewall 322.

The lateral discharge portions 324 may be formed in various shapes such as holes or slits that penetrate the flange sidewall 322.

According to certain embodiments of the present disclosure, the rotation flange 320 may include a drive shaft coupling portion 325 formed at its center.

The drive shaft coupling portion 325 may be formed as a through-hole penetrating vertically through the center of the rotation flange 320, and may be connected to a drive shaft of a drive unit 370 coupled to a lower side of the boat support unit 300. Accordingly, the rotation flange 320 may be rotated by the operation of the drive unit 370.

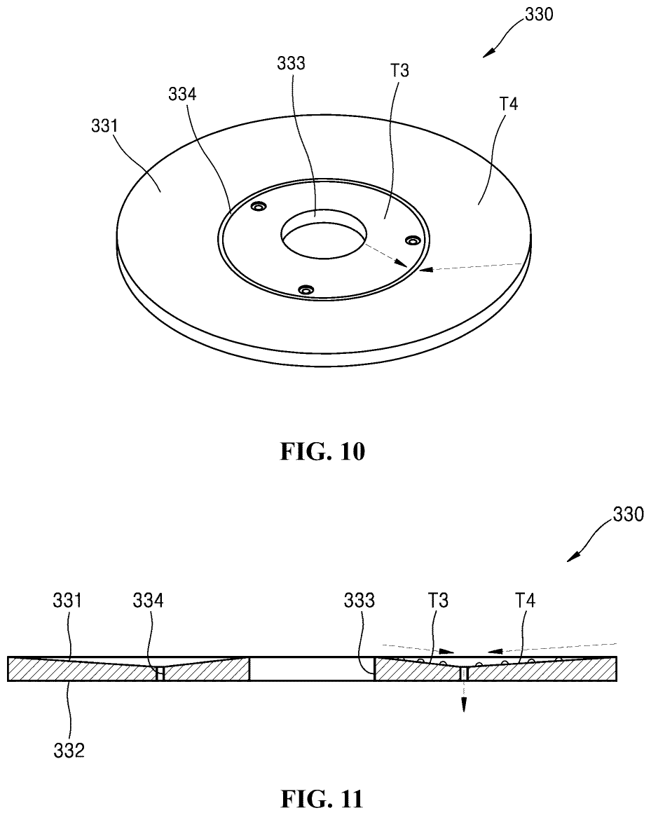

FIG. 10 is a perspective view illustrating a shield plate 330 of the boat support unit 300 according to an embodiment of the present disclosure, and FIG. 11 is a cross-sectional view of the shield plate 330.

As shown in FIGS. 2 through 4, the shield plate 330 may be coupled to an upper surface of the cap flange 340 to protect it from corrosive gases.

Specifically, the shield plate 330 may be formed of quartz and may be attached so as to cover the upper surface of the cap flange 340, which may be formed of metal. Accordingly, the shield plate 330 may protect the cap flange 340 from process gases flowing inside the boat support unit 300.

More specifically, the shield plate 330 may include a shield upper surface portion 331, a shield lower surface portion 332, and a shield through-hole 334.

As illustrated in FIGS. 10 and 11, the shield upper surface portion 331 may be the upper surface of the shield plate 330, and at least a portion of the shield upper surface portion 331 may be formed with an inclined region configured to collect fluid falling from above and guide it downward. The shield lower surface portion 332 may be the lower surface of the shield plate 330 and may be coupled to the cap flange 340.

The shield upper surface portion 331 may include the inclined region in which at least one portion has a third slope T3 and at least another portion has a fourth slope T4.

For example, as shown in FIGS. 10 and 11, the shield upper surface portion 331 may be formed to slope gradually downward from the center thereof toward a shield through-hole 334, and also slope gradually downward from the edge thereof toward the shield through-hole 334.

Accordingly, fluid that drops directly from the thermal cap 310 through the plurality of through-holes 323 of the rotation flange 320, or that flows downward through the through-holes 323 and the lateral discharge portions 324, may be guided from the edge or center of the shield upper surface portion 331 toward the shield through-hole 334.

As shown in FIGS. 10 and 11, the shield through-hole 334 may be formed at a point spaced a predetermined distance from the center of the shield plate 330 and may penetrate from the shield upper surface portion 331 to the shield lower surface portion 332.

The shield through-hole 334 may be formed either as a hole portion that vertically penetrates in a hole shape from an upper side to a lower side in a radially equiangular arrangement with respect to the center of the shield plate 330, or as a slit portion that penetrates in a slit shape.

According to certain embodiments of the present disclosure, the shield plate 330 may include a shield center portion 333.

The shield central portion 333 may be formed as a through-hole portion that vertically penetrates the center of the shield plate 330 and may be configured to allow a portion of a drive unit 370, which is coupled from below the boat support unit 300, to pass through so as to connect with the rotation flange 320 located above.

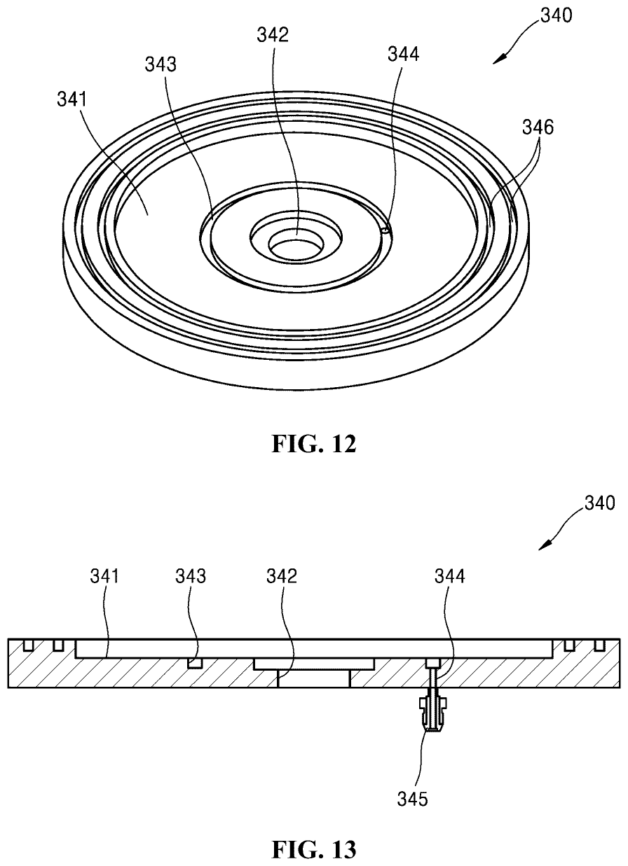

FIG. 12 is a perspective view illustrating a cap flange 340 of the boat support unit 300 according to an embodiment of the present disclosure, and FIG. 13 is a cross-sectional view of the cap flange 340.

As shown in FIGS. 2 through 4, the cap flange 340 may be formed below the rotation flange 320 and may support the entire boat support unit 300 so that it can be vertically driven.

The cap flange 340 may include a shield seating portion 341, a drive coupling portion 342, a discharge guide groove 343, and a bottom discharge portion 344.

As illustrated in FIGS. 12 and 13, the shield seating portion 341 may be a region on the upper surface of the cap flange 340 where the shield plate 330 is seated.

For example, the shield seating portion 341 may be formed as a recessed circular groove on the upper surface of the cap flange 340, excluding its outer edge, and the shield plate 330 may be seated within this circular groove.

The discharge guide groove 343 may be formed as a ring-shaped groove centered around the center of the cap flange 340 at a predetermined radial distance.

As shown in FIG. 4, the discharge guide groove 343 may be formed in the shield seating portion 341 and may be formed as a ring-shaped groove at a position corresponding to the shield through-hole 334 of the shield plate 330. Accordingly, fluid discharged through the shield through-hole 334 may be introduced only into the discharge guide groove 343 of the cap flange 340.

The discharge guide groove 343 may include the inclined region formed in a direction toward the bottom discharge portion 344. Accordingly, fluid discharged through the shield through-hole 334 may flow toward the bottom discharge portion 344.

The bottom discharge portion 344 may be formed to vertically penetrate the cap flange 340 at one or more locations of the discharge guide groove 343.

Fluid guided into the discharge guide groove 343 may be discharged to the outside of the cap flange 340 through the bottom discharge portion 344. The bottom discharge portion 344 may be connected to a discharge port 345 formed on the outer side of the cap flange 340 so that the fluid can be easily discharged.

As shown in FIG. 2, the cap flange 340 may be provided with a drive coupling portion 342 at a central region thereof, to which the drive unit 370 is coupled. Specifically, the drive coupling portion 342 may be formed as a through-hole that vertically penetrates the central region of the cap flange 340, allowing the drive unit 370 to be coupled thereto.

In this configuration, the drive unit 370 may be formed with a sealing structure within the boat support unit 300 so as to maintain the reaction space A inside the reaction tube unit 100 in a sealed state from the external environment.

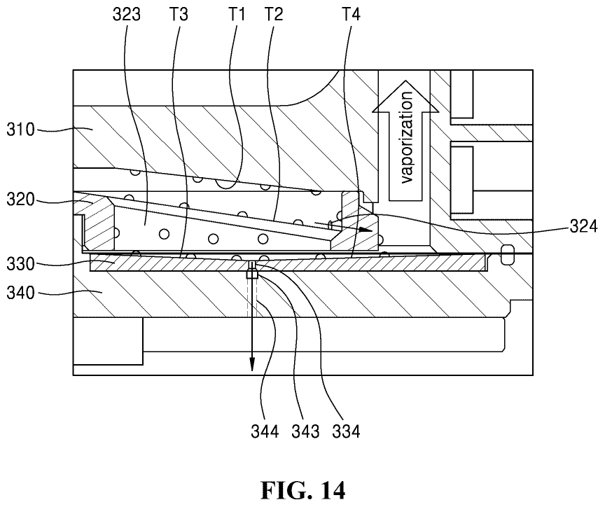

FIG. 14 is a diagram illustrating the discharge of fluid from the boat support unit 300 according to an embodiment of the present disclosure.

As illustrated in FIG. 14, fluid formed by the liquefaction of H₂O vaporized and rising from a lower region of the boat support unit 300 may condense on a thermal cap lower surface portion 311 of the thermal cap 310.

At this time, the fluid may flow along a first slope T1 on the thermal cap lower surface portion 311 toward its edge and may drop downward.

The fluid falling downward may flow along a second slope T2 on the flange upper surface portion 321 of the rotation flange 320 toward its edge and may either drop further downward through the lateral discharge portions 324 or fall directly onto the shield plate 330.

Fluid that reaches the shield plate 330 may flow in a downward direction along either a third slope T3 or a fourth slope T4 and may pass through the shield through-hole 334.

The fluid guided from the shield plate 330 into the discharge guide groove 343 of the cap flange 340 may be discharged through a bottom discharge portion 344.

Subsequently, the fluid discharged from the boat support unit 300 may pass through a scrubber and be ultimately drained into a drain tank.

The boat support unit 300 of the substrate processing apparatus 1000 according to the present disclosure may include the thermal cap 310, the rotation flange 320, the shield plate 330, and the cap flange 340, but is not necessarily limited thereto. The boat support unit 300 may be formed by a combination of at least one or more of the above components. In addition, the inclined region of the boat support unit 300 may include at least one of a first slope T1, a second slope T2, a third slope T3, and a fourth slope T4.

According to certain embodiments of the present disclosure, the boat support unit 300 may include a boat flange 360 positioned in an intermediate region of the thermal cap 310.

When the boat support unit 300 is elevated and coupled below the reaction tube unit 100, the boat flange 360 may include a reaction tube seating portion 361 on which the lower end of the reaction tube unit 100 may be seated. In this case, the boat flange 360 may be positioned in the intermediate region of the thermal cap 310 so that the upper region of the thermal cap 310 is in the reaction space of the reaction tube unit 100.

The boat flange 360 may be coupled to the cap flange 340 via a cylindrical cap frame 345. That is, a lower region of the thermal cap 310 may be positioned inside the cap frame 345.

As illustrated in FIG. 2, the cap frame 345 may be coupled to the upper side of the cap flange 340, and at least a portion of the cap frame 345 may be configured to cover the edge of the shield plate 330.

According to certain embodiments of the present disclosure, as shown in FIG. 2, the boat support unit 300 may include a side heater H1, a bottom heater H2, and a manifold portion M.

The side heater H1 may include a heater formed on the outer side of the cap frame 345, and the bottom heater H2 may include a heater formed below the cap flange 340. The side heater H1 and bottom heater H2 may raise the internal temperature of the boat support unit 300 to promote vaporization of H₂O and reduce condensation, thereby preventing thermal loss in the lower region of the boat support unit 300. In addition, the heaters may prevent powder from forming in the manifold portion M formed inside the boat support unit 300.

The manifold portion M may be formed inside the cap frame 345 and may include ports for supplying process gas to the reaction space A or exhausting treated gas therefrom.

In the substrate processing apparatus according to the present disclosure, the boat support unit has an inclined region formed in at least a portion thereof to allow fluid to flow downward. This structural configuration prevents corrosion of internal components caused by the generated fluid and enables the liquefied fluid to be guided toward a scrubber, thereby preventing damage to the drain tank during the cleaning process.

The present disclosure has been described with reference to the illustrated embodiments, which are merely exemplary. It will be understood by those skilled in the art that various modifications and equivalent alternatives may be made based on the disclosure. Therefore, the true scope of protection of the present disclosure should be defined by the technical spirit set forth in the appended claims.

What is claimed is:

1. A substrate processing apparatus comprising:
a reaction tube unit having a reaction space formed therein in which a plurality of substrates are processed, the reaction tube unit having an open lower end;
a boat unit disposed inside the reaction tube unit, the boat unit being configured to support the plurality of substrates in a vertically stacked arrangement; and
a boat support unit configured to support the boat unit and to move the boat unit vertically so as to position the boat unit within the reaction space of the reaction tube unit, wherein at least a portion of one surface of the boat support unit includes an inclined region, such that liquefied fluid in the reaction space is discharged downward.

2. The substrate processing apparatus of claim 1, wherein the boat support unit comprises:
a thermal cap formed below the boat unit, the thermal cap including an internal heat-insulating region configured to prevent heat loss from a lower region of the reaction space near an outer side of the boat support unit;
a rotation flange installed below the thermal cap and connected to a drive unit disposed below the boat support unit, the rotation flange being configured to rotate by a driving force of the drive unit and to transmit the rotational force to the thermal cap and the boat unit;
a cap flange formed below the rotation flange, the cap flange being coupled to the drive unit at a central region and configured to support the entire boat support unit and drive the boat support unit vertically; and
a shield plate coupled to an upper surface of the cap flange to protect the upper surface of the cap flange from corrosive gas.

3. The substrate processing apparatus of claim 1, wherein the boat support unit comprises a thermal cap formed below the boat unit, the thermal cap including an internal heat-insulating region configured to prevent heat loss from a lower region of the reaction space near an outer side of the boat support unit, and wherein a lower surface of the thermal cap is formed to slope gradually downward from a central region to an edge region.

4. The substrate processing apparatus of claim 1, wherein the boat support unit comprises a thermal cap formed below the boat unit, the thermal cap including an internal heat-insulating region configured to prevent heat loss from a lower region of the reaction space near an outer side of the boat support unit, and wherein at least a portion of a lower surface of the thermal cap includes the inclined region having a first slope.

5. The substrate processing apparatus of claim 1, wherein the boat support unit comprises a rotation flange connected to a drive unit formed below the boat support unit, the rotation flange being rotated by a driving force of the drive unit and transmitting the rotational force to the boat unit, and wherein the rotation flange comprises:
a flange upper surface portion formed to slope gradually downward from a central region toward an edge region of the rotation flange;
a plurality of through-holes formed to penetrate vertically through the rotation flange and arranged at radially equiangular intervals with respect to the center of the rotation flange; and
a plurality of lateral discharge portions formed to penetrate from an inner side to an outer side of a flange sidewall that surrounds the perimeter of the rotation flange and is formed higher than the flange upper surface portion, the lateral discharge portions being located at positions corresponding to the flange upper surface portion.

6. The substrate processing apparatus of claim 1, wherein the boat support unit comprises a rotation flange connected to a drive unit formed below the boat support unit, the rotation flange being rotated by a driving force of the drive unit and transmitting the rotational force to the boat unit, and wherein at least a portion of a flange upper surface portion of the rotation flange includes the inclined region having a second slope.

7. The substrate processing apparatus of claim 1, wherein the boat support unit comprises a shield plate coupled to an upper surface of a cap flange configured to support the boat support unit and drive the boat support unit vertically, the shield plate being configured to protect the upper surface of the cap flange from corrosive gas, and wherein the shield plate comprises:
a shield upper surface portion, at least a portion of which is formed with the inclined region; and
a shield through-hole formed at a position spaced a predetermined distance from a center of the shield plate and penetrating through the shield plate.

8. The substrate processing apparatus of claim 7, wherein the shield through-hole comprises a plurality of hole portions or slit portions formed to penetrate vertically through the shield plate and arranged at radially equiangular intervals with respect to the center of the shield plate.

9. The substrate processing apparatus of claim 7, wherein the shield upper surface portion is formed such that both a central region and an edge region of the shield upper surface portion slope gradually downward toward the shield through-hole.

10. The substrate processing apparatus of claim 7, wherein the shield plate includes the inclined region formed such that at least a portion of the shield upper surface portion of the shield plate has a third slope, and at least another portion of the shield upper surface portion has a fourth slope.

11. The substrate processing apparatus of claim 1, wherein the boat support unit comprises a cap flange to which the drive unit formed below the boat support unit is coupled at a central region thereof, the cap flange being configured to support the entire boat support unit for vertical movement, and wherein the cap flange comprises:
a shield seating portion on an upper surface of the cap flange on which the shield plate is seated;
a drive coupling portion formed to vertically penetrate through a central region of the cap flange so that the driving unit is coupled thereto;
a discharge guide groove portion formed in a ring shape at a predetermined radial distance from a central point of the cap flange; and
a bottom discharge portion formed to penetrate vertically through the cap flange at one or more locations of the discharge guide groove portion
